(19) United States
(12) Patent Application Publication
(10) Pub. No.: US 2025/0337378 A1
(43) Pub. Date: Oct. 30, 2025

(54) POWER AMPLIFIER COMBINER

(71) Applicant: TEXAS INSTRUMENTS INCORPORATED, Dallas, TX (US)

(72) Inventors: Zheng Liu, Richardson, TX (US); Siraj Akhtar, Richardson, TX (US)

(21) Appl. No.: 18/651,514

(22) Filed: Apr. 30, 2024

(51) Int. Cl. H03F 3/60; H03F 1/02; H03F 3/24

(52) U.S. Cl. CPC H03F 3/602; H03F 1/0288; H03F 3/245; H03F 2200/198; H03F 2200/336; H03F 2200/54

(57) ABSTRACT

Described is an apparatus a first amplifier (carrier or main) having a first amplifier output and configured to provide a first signal having a first power level at the first amplifier output. The apparatus further comprises a second amplifier (peaking or auxiliary) having a second amplifier output and configured to provide a second signal having a second power level at the second amplifier output, the second power level being higher than the first power level. The apparatus further comprises a combiner circuit having a quadrature-phase terminal (thru), an in phase terminal (couple), a reference terminal (reference), and an isolation terminal (isolation), the in phase terminal coupled to the first amplifier output, the quadrature phase terminal coupled to the second amplifier output, the reference terminal coupled to a combiner output, and the isolation terminal coupled to a direct current (DC) voltage source.

### BACKGROUND

High-capacity wireless communication in 5G and beyond poses challenges for power amplifiers (PAs) to process signals with high peak to average power ratio (PAPR). It is also desirable for a power amplifier to provide high deep back-off efficiency and wideband of operation to support the wireless communication.

### SUMMARY

Described is an apparatus of a first amplifier (carrier or main) having a first amplifier output and configured to provide a first signal having a first power level at the first amplifier output, in accordance with at least one example. In at least one example, the apparatus further comprises a second amplifier (peaking or auxiliary) having a second amplifier output and configured to provide a second signal having a second power level at the second amplifier output, the second power level being higher than the first power level. In at least one example, the apparatus further comprises a combiner circuit having a quadrature-phase terminal (thru), an in phase terminal (couple), a reference terminal (reference), and an isolation terminal (isolation). The in phase terminal is coupled to the first amplifier output, the quadrature phase terminal is coupled to the second amplifier output, the reference terminal is coupled to a combiner output, and the isolation terminal is coupled to a direct current (DC) voltage source.

Described is an apparatus comprising a transmit circuit having a transmit input, a first transmit output, and a second transmit output. In at least one example, the apparatus comprises a first amplifier (carrier or main) having a first amplifier input and a first amplifier output, the first amplifier input coupled to the first transmit output. In at least one example, the apparatus comprises a second amplifier (peaking or auxiliary) having a second amplifier input and a second amplifier output, the second amplifier input coupled to the second transmit output, and the first and second amplifiers having different power levels at saturation. In at least one example, the apparatus comprises a quadrature hybrid combiner coupled between the first and second amplifier outputs and a combiner output.

Described is a method comprising receiving a first signal and responsive to a power level of the first signal being below a threshold providing a second signal having a first power level using a first amplifier to an in phase terminal of a quadrature hybrid combiner. In at least one example, responsive to a power level of the first signal being above the threshold, the method comprises providing a third signal having a second power level using the first amplifier to the in phase terminal. In at least one example, the method comprises providing a fourth signal having a third power level higher than the first and second power levels using a second amplifier to a quadrature phase terminal of the quadrature hybrid combiner. In at least one example, the method comprises providing a fifth signal at a reference terminal of quadrature hybrid combiner based on the second signal or a combination of the third and fourth signals as an output signal.

### BRIEF DESCRIPTION OF THE DRAWINGS

The examples will be understood more fully from the detailed description given below and from the accompanying drawings, which, however, should not be taken to limit the disclosure to the specific examples, but are for explanation and understanding only.

FIG. 1 is a schematic of a power amplifier, in accordance with at least one example.

FIG. 2A is a plot illustrating transient peak and average power for a communication signal received at an input of a power amplifier, in accordance with at least one example.

FIG. 2B is a plot illustrating power density function and efficiency as a function of back-off power for a power amplifier, in accordance with at least one example.

FIG. 3 is a schematic of a quadrature hybrid coupler of the power amplifier of FIG. 1, in accordance with at least one example.

FIG. 4 is a schematic of a branch-line coupler of the power amplifier of FIG. 1, in accordance with at least one example.

FIG. 5 is a schematic of a Lange coupler of the power amplifier of FIG. 1, in accordance with at least one example.

FIG. 6 is a schematic of a transformer coupler of the power amplifier of FIG. 1, in accordance with at least one example.

FIG. 7 is a schematic of a circuit including a transformer coupler and capacitors at the ports that can be part of the power amplifier of FIG. 1, in accordance with at least one example.

FIGS. 8A-B are plots showing a first coupling factor and associated phase imbalance as a function of frequency, respectively, in accordance with at least some examples.

FIGS. 8C-D are plots showing a second coupling factor and associated phase imbalance as a function of frequency, respectively, in accordance with at least some examples.

FIGS. 8E-F are plots showing a third coupling factor and associated phase imbalance as a function of frequency, respectively, in accordance with at least some examples.

FIG. 9 is a schematic of a power amplifier with a transformer coupler and capacitors at the ports, in accordance with at least one example.

FIG. 10A is a plot showing current profiles of a main amplifier and an auxiliary amplifier of the power amplifier of FIG. 9 as a function of back-off power, in accordance with at least one example.

FIG. 10B is a plot showing percentage contribution of powers of the main amplifier and the auxiliary amplifier on the input power as input power or output power increase, in accordance with at least one example.

FIG. 11 is a plot showing efficiency of power amplifier of FIG. 9 as a function of back-off power at different frequencies, in accordance with at least one example.

FIG. 12 is a schematic of a power amplifier with a transformer coupler with center taps and coupling capacitors at the ports and the center taps, in accordance with at least one example.

FIG. 13A is a plot showing efficiency of the power amplifier of FIG. 12 as a function of back-off power at different frequencies, in accordance with at least one example.

FIG. 13B is a plot showing efficiency of the power amplifier of FIG. 12 for different back-off powers at a center frequency f0, in accordance with at least one example.

FIG. 14 is a schematic of a power amplifier with a transformer coupler with center taps and coupling capacitors at the ports and the center taps, in accordance with at least one example.

FIG. 15 is a schematic of a power amplifier with a transformer coupler with center taps and coupling capacitors at the ports and the center taps, and with a 1:n transformer, in accordance with at least one example.

FIG. 16A-C are schematics of power amplifiers with different coupling coefficients, transformer sizes, and back-off powers, in accordance with at least some examples.

FIG. 17 is a set of plots that show the influence of second harmonic impedance.

FIG. 18A is a schematic showing setup for determining input impedance at second harmonic frequencies at through port and couple port, in accordance with at least one example.

FIG. 18B is a set of Smith charts showing load impedances at second harmonic frequencies for the amplifiers connected to the couple and through ports of a power amplifier, in accordance with at least one example.

FIG. 19 is a schematic of a power amplifier with selectable combiners, in accordance with at least one example.

FIG. 20 is a flowchart of a method of operating a power amplifier, in accordance with at least one example.

### DETAILED DESCRIPTION OF EXAMPLE EMBODIMENTS

As described above, high-capacity wireless communication in 5G and beyond poses challenges for power amplifiers (Pas) to process signals with high peak to average power ratio (PAPR). A power amplifier may also need to provide high deep back-off efficiency and wideband of operation to support the wireless communication.

In at least one example, a power amplifier is described includes a transformer-based quadrature hybrid combiner. The transformer-based quadrature hybrid combiner is a 4-port device including a reference port, a through port, a couple port, and an isolation port. In at least one example, the load is coupled to the reference port, and the isolation port is either coupled to ground or to a power supply rail. In at least one example, the power amplifier comprises asymmetrical amplifiers coupled to the through port and the couple port of the transformer-based quadrature hybrid combiner.

The asymmetrical amplifiers include a main amplifier (or a carrier amplifier) and an auxiliary amplifier (or a peaking amplifier). In at least one example, the amplifiers are asymmetrical in that they are configured (e.g., based on different bias currents, different transistor sizes, etc.) to provide different output power levels at saturation. In at least one example, the auxiliary amplifier has a higher output power level at saturation than the main amplifier. In at least one example, the main amplifier is coupled to the couple port and the auxiliary amplifier is coupled to the through port of the transformer-based quadrature hybrid combiner. In at least one example, coupling capacitors are provided that couple between terminals of inductors (e.g., primary and secondary windings) of the transformer-based quadrature hybrid combiner. In at least one example, additional capacitors are coupled between the terminals of the inductors and to a reference rail (e.g., ground). In at least one example, the main amplifier is a class AB amplifier. In at least one example, the auxiliary amplifier is a class C amplifier.

In at least one example, an input power signal (e.g., a 5G signal with any suitable modulation) is received by a power divider, which divides the input power signal for input to the main amplifier and the auxiliary amplifier. For example, the input power signal is divided into a first signal and a second signal, where the first signal is provided to the main amplifier and the second signal is provided to the auxiliary amplifier. In at least one example, the main amplifier operates by amplifying the first signal, while the auxiliary amplifier is off. Upon crossing a power threshold, the auxiliary amplifier turns on and amplifies the second signal while the main amplifier operates in saturation. The outputs of the main and auxiliary amplifiers are combined by the transformer-based quadrature hybrid combiner and provided to the reference port where the load is coupled.

In at least one example, any back-off power (e.g., 6 dB to deep back-off levels) is achieved by the power amplifier by modifying the capacitance ratios of the capacitors coupled to the inductors of the transformer-based quadrature hybrid combiner, by changing the coupling coefficient between the inductors, and/or power levels of the main and auxiliary amplifiers. The use of a transformer can reduce the size of the power amplifier (e.g., compared with other implementations that use transmission lines as the matching network). The transformer based coupler or combiner of the amplifier also provides a higher bandwidth and efficiency compared to transmission lines that are designed for narrowband operation. In at least one example, the isolation port of the transformer-based quadrature hybrid combiner is shorted to ground (or coupled to a power supply rail), which allows for the outputs of the main and auxiliary amplifiers to combine at the reference port (output port) without (or with reduced) loss.

Examples of power amplifier described herein can provide deep back-off enhancement (e.g., >6 dB), which allows the power amplifier to process signals with high peak to average power ratio (PAPR) with high efficiency, in which the main amplifier (with a lower output power level) is enabled and the auxiliary amplifier (with a higher output power level) when input power level is below a threshold, and the auxiliary amplifier is enabled when the input power level exceeds the threshold. Moreover, the transformer-based quadrature hybrid combiner has a smaller footprint and a width bandwidth (e.g., compared with combiners with transmission lines, or combiners with multiple transformers), which allows the power amplifier to be integrated within a semiconductor package and support broadband operation.

In the drawings, like reference numerals refer to like elements throughout, and the various features are not necessarily drawn to scale. Here, the same reference numbers or other reference designators are used in the drawings to designate the same or similar (either by function and/or structure) features.

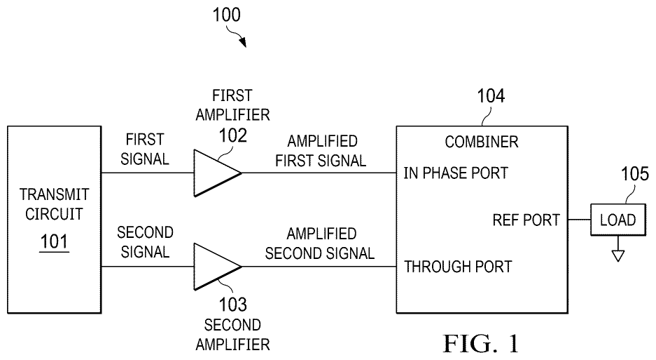

FIG. 1 is a schematic of a power amplifier (PA) 100, in accordance with at least one example. In at least one example, power amplifier 100 comprises a transmit circuit 101, a first power amplifier 102, a second power amplifier 103, and a combiner 104, which is coupled to a load 105. Power amplifier 100 can have a Doherty amplifier configuration. Transmit circuit 101 is a power divider or a power splitter that receives an input signal and divides or splits the input signal into a first signal and a second signal. The input signal can be any signal such as a modulated 5G communication signal with 256 quadrature amplitude modulation (QAM). The input signal may have high peak to average power ratio (PAPR), such as 6 dB and higher.

In at least one example, combiner 104 is a 4-port network including a reference port, a through port, a couple port, and an isolation port. In at least one example, load 105 is coupled to the reference port, and the isolation port is either coupled to ground or to a power supply rail. In at least one example, combiner 104 is a quadrature hybrid power combiner. In at least one example, the quadrature hybrid power combiner is implemented as a transformer having primary and secondary windings. In at least one example, combiner 104 is a Branch line hybrid power combiner. In at least one example, combiner 104 is a Lange hybrid power combiner.

In at least one example, first amplifier 102 and second amplifier 103 are asymmetrical amplifiers configured (e.g., based on different DC bias currents, different transistor sizes, etc.) to have different output power levels at saturation. In at least one example, the first signal is provided to first amplifier 102 (e.g., a main amplifier) and is coupled to an in phase port (or couple port) of combiner 104. In at least one example, the second signal is provided to second amplifier 103 (e.g., an auxiliary amplifier), which is coupled to a through port of combiner 104. In at least one example, first amplifier 102 is configured to provide a first output power level at saturation and second amplifier 103 is configured to provide a second output power level at saturation, and the second output power level is higher than the first output power level. In at least one example, first amplifier 102 operates by amplifying the first signal while second amplifier 103 is off. Upon the input signal power increasing above a threshold, second amplifier 103 turns on and amplifies the second signal while first amplifier 102 operates by amplifying the first signal. In at least one example, upon input signal power increasing, the output power level of first amplifier 102 also increases. The outputs of first and second power amplifiers 102 and 103, respectively, are combined by combiner 104 and provided to the reference port where load 105 is coupled. In at least one example, first power amplifier 102, second power amplifier 103, and combiner 104 are part of an integrated circuit (IC).

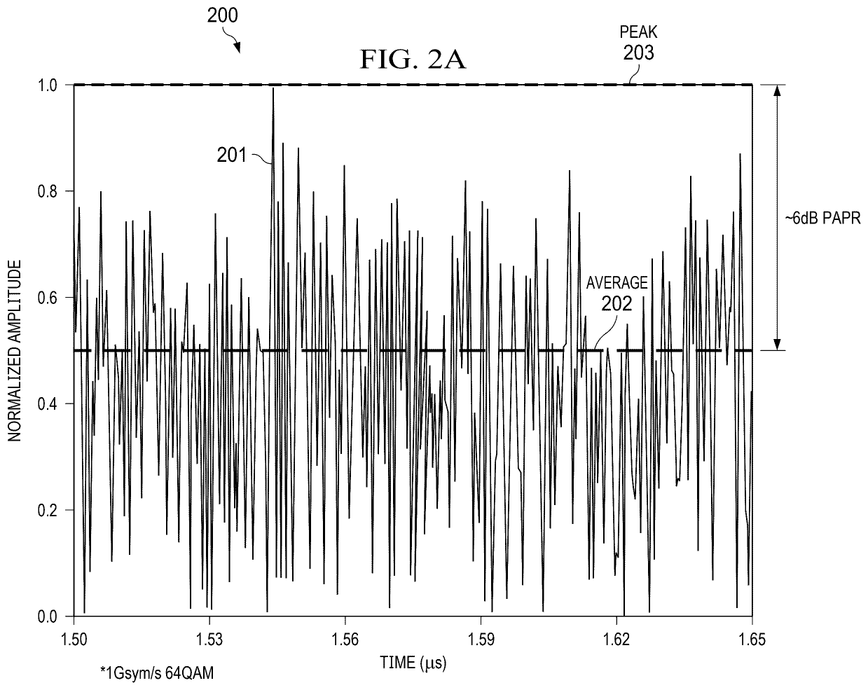

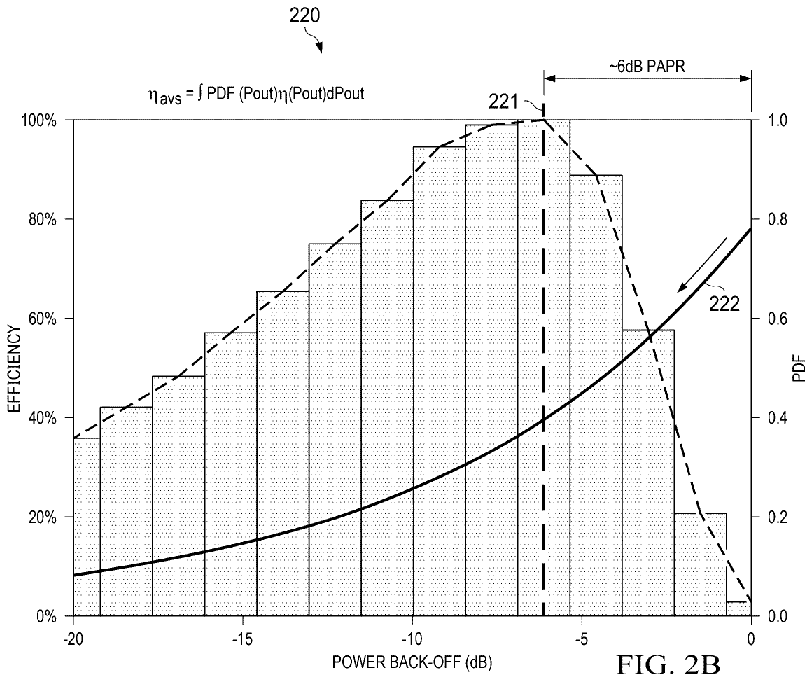

FIG. 2A is a plot 200 illustrating transient peak and average power for a communication signal received at an input of the power amplifier, in accordance with at least one example. Here, the x-axis is time, and the y-axis is normalized amplitude. FIG. 2B is a plot 220 illustrating power density function and efficiency as a function of back-off power for the power amplifier, in accordance with at least one example. Here, x-axis is back-off power level, and y-axis is efficiency of the power amplifier and power density function (PDF). A modulated input signal 201 may have a high PAPR, which is indicated by a difference of amplitude levels 202 and 203. Since most of the signal is not operating at peak levels, the power amplifier is designed to operate at back-off power levels such as back-off level 221 to amplify the input signal(s) where most signal(s) reside. Waveform 222 of plot 220 indicates that the efficiency of a PA reduces as power decreases. Examples of a power amplifier described herein can maintain a higher efficiency at various back-off power levels.

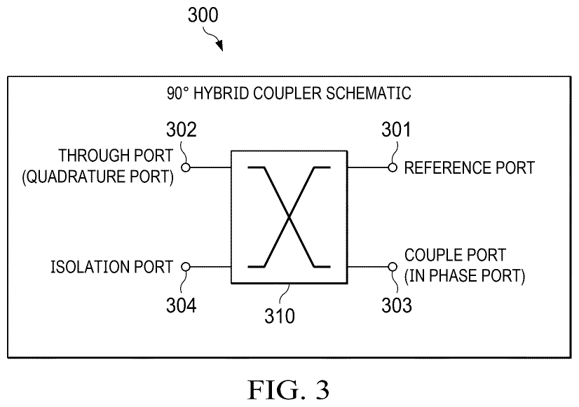

FIG. 3 is a schematic of a quadrature hybrid coupler 300, which can be an example of combiner 104 of FIG. 1, in accordance with at least one example. In at least one example, quadrature hybrid coupler 300 is a 4-port network including a reference port 301, a through port 302 (quadrature port), a couple port 303 (in phase port), and an isolation port 304. The four ports are coupled to a combiner 310. In at least one example, quadrature hybrid coupler 300 is a 90 degrees hybrid coupler. A 90 degrees hybrid coupler is operable to split an input signal into two paths with a 90-degree phase shift between them or to combine two signals, while maintaining high isolation between them. For instance, an input signal is received at reference port 301 and is divided by the 90 degrees hybrid coupler between through port 302 (a first output port) and couple port 303 (a second output port) with half the power flowing to couple port 303 (in phase or 0° phase shift port) and the other half flowing to through port 302 (quadrature phase or 90° phase shift port). In at least one example, quadrature hybrid coupler 300 is configured as a combiner where a first input signal is provided to couple port 303 (in phase or 0° phase shift port) and a second input signal is provided to through port 302 (quadrature phase or 90° phase shift port), and an output signal that combines the first input signal and the second input signal is provided to reference port 301.

In at least one example, an output of first power amplifier 102 is coupled to couple port 303 and an output of second power amplifier 103 is coupled to through port 302. In at least one example, load 105 is coupled to reference port 301. In at least one example, isolation port 304 is either coupled to ground or to a power supply rail.

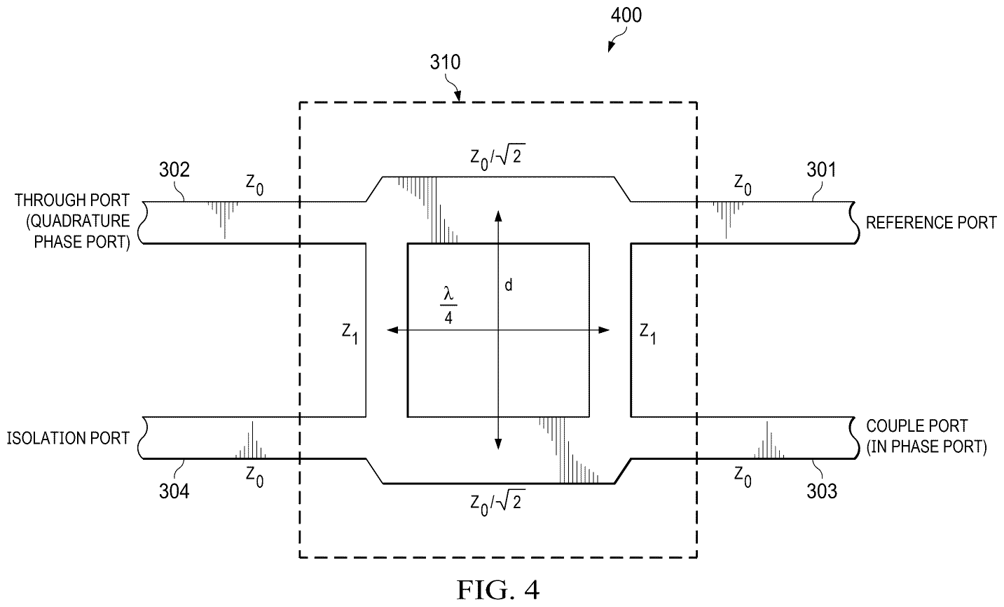

FIG. 4 is a schematic of a branch-line coupler 400 of the power amplifier, in accordance with at least one example. In at least one example, combiner 310 comprises branch-line coupler 400. In at least one example, reference port 301, through port 302 (quadrature port), couple port 303 (in phase port), isolation port 304, and combiner 310 are implemented as microstrip lines patterned on a dielectric substrate, where Zo is the characteristic impedance of the microstrip line. In at least one example, each microstrip line within combiner 310 has a quarter-wavelength (λ/4) at a target frequency. Two of the microstrip lines of combiner 310 have

$$\frac{1}{\sqrt{2}} {Z}_{0}$$

impedance between reference port 301 and through port 302, and between couple port 303 and isolation port 304. Two of the microstrip lines of combiner 310 have Z₁ between reference port 301 and through port 302, and between couple port 303 and isolation port 304, where Z₁ is different from Z₀. Also, the separation between the two microstrip lines with

$$\frac{1}{\sqrt{2}} {Z}_{0}$$

impedance is at λ/4, and the separation between the two microstrip lines with Z₁ impedance is at a distance d different from λ/4. Such arrangements can provide an unequal S31 and S21 parameters which, as to be described below, allow tuning of the coupling factor K to introduce amplitude imbalance.

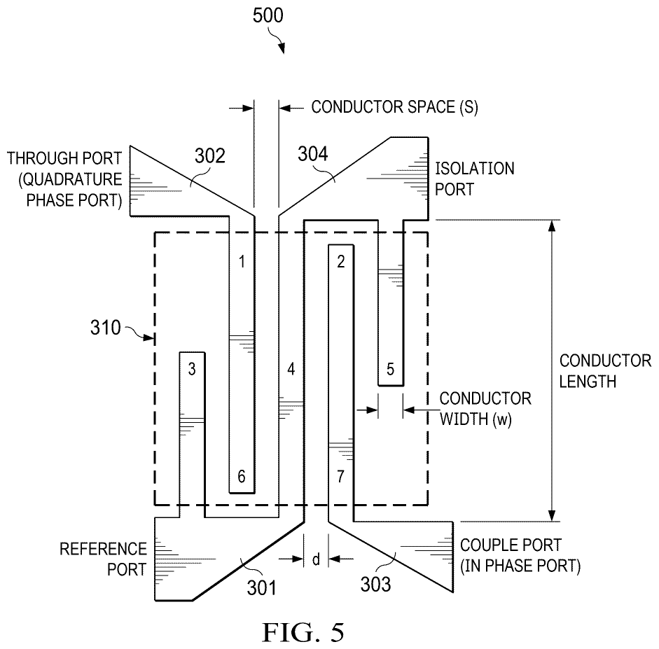

FIG. 5 is a schematic of a Lange coupler 500 of the power amplifier, in accordance with at least one example. In at least one example, combiner 310 comprises Lange coupler 500, which is an example of a quadrature hybrid coupler. Lange coupler 500 is a 4-port interdigitated structure where coupling is derived from closely spaced metal lines such as microstrip lines. In at least one example, the number of conductors of fingers in combiner 310 is even. The length of the fingers is set by a center frequency (f0). In at least one example, the finger length is equal to a quarter wavelength of f0 such that Lange coupler 500 is designed for a target coupling (e.g., 3 dB or any dB) between reference port 301 and the couple port 303 and isolation port 304. In at least one example, the distance ‘d’ between spaced metal lines can be adjusted to control the coupling factor of Lange coupler 500. In at least one example, the distance ‘d’ is adjusted to realize an asymmetrical quadrature hybrid where dB (S21) is not equal to dB (S31).

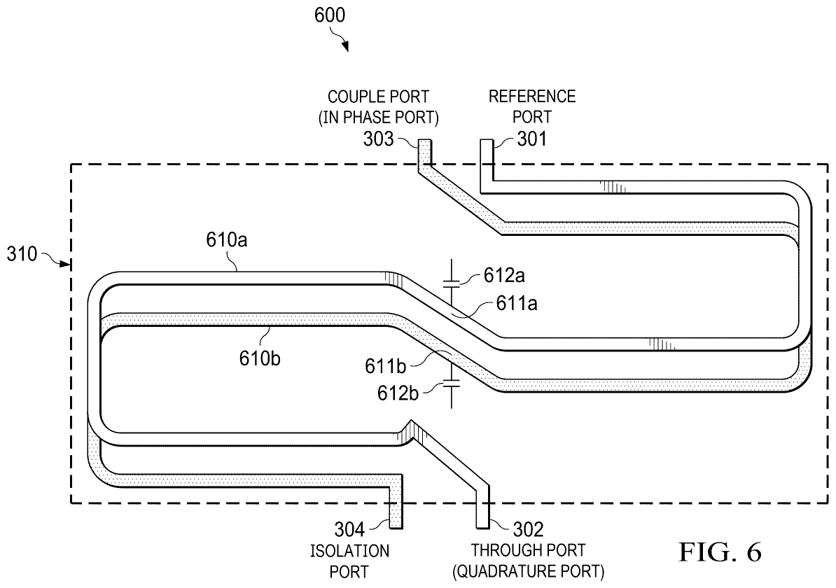

FIG. 6 is a schematic of a transformer coupler 600 of the power amplifier, in accordance with at least one example. In at least one example, combiner 310 comprises transformer coupler 600, which includes a transformer configured as a quadrature hybrid coupler. In at least one example, reference port 301, through port 302 (quadrature port), couple port 303 (in phase port), isolation port 304, and combiner 310 are implemented in two windings or coils 610a and 610b. In at least one example, windings or coils 610a and 610b may at least partially overlap. Any shape may be used for windings or coils 610a and 610b. In at least one example, capacitors are coupled to center taps of windings or coils 610a and 610b. For instance, at center tap 611a of winding or coil 610a, capacitor 612a is coupled at one end while another end is coupled to a ground or supply rail. In at least one example, at center tap 611b of winding of coil 610b, capacitor 612b is coupled at one end, while another end is coupled to a ground or supply rail.

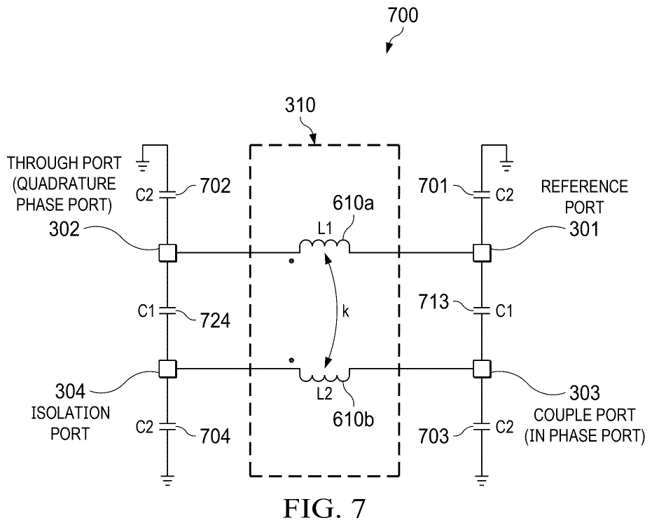

FIG. 7 is a schematic of a circuit 700 with a transformer coupler and coupling capacitors at the ports, in accordance with at least one example. In at least one example, circuit 700 comprises a transformer as combiner 310. One such example of the transformer is transformer coupler 600, where ‘k’ is the coupling coefficient between windings or coils 610a and 610b. In some examples, combiner 310 can include examples of combiners described in FIG. 4 and FIG. 2. Here, winding or coil 610a has inductance L1 and winding or coil 610a has inductance L2. In at least one example, a first capacitor 701 with capacitance C2 is coupled to reference port 301 and ground. In at least one example, a second capacitor 702 with capacitance C2 is coupled to through port 302 and ground. In at least one example, a third capacitor 703 with capacitance C2 is coupled to couple port 303 and ground. In at least one example, a fourth capacitor 704 with capacitance C2 is coupled to isolation port 304 and ground. In at least one example, circuit 700 includes capacitors coupled between terminals of windings or coils 610a and 610b. In at least one example, a first capacitor 713 with capacitance Cl is coupled between reference port 301 and couple port 303. In at least one example, a second coupling capacitor 724 with capacitance C1 is coupled between through port 302 and isolation port 304. In at least one example, first, second, third, and fourth capacitors 701, 702, 703, and 704, respectively, and first and second coupling capacitors 724 and 713, respectively, provide additional knobs to move back-off power for power amplifier 700. In at least one example, first power amplifier 102 is coupled to couple port 303, while second power amplifier 103 is coupled to through port 302.

In at least one example, one or more of first, second, third, and fourth capacitors 701, 702, 703, and 704, respectively, and/or first and second coupling capacitors 724 and 713, are varactors with adjustable capacitance. In at least one example, one or more of first, second, third, and fourth capacitors 701, 702, 703, and 704, respectively, and/or first and second capacitors 724 and 713 have adjustable capacitance. For example, one or more of first, second, third, and fourth capacitors 701, 702, 703, and 704, respectively, and/or first and second capacitors 724 and 713 can have a network of programmable capacitor segments between two capacitor terminals, and the capacitor segments can be connected to or disconnected from the capacitor terminals by switches (e.g., transistors) to decrease or increase overall capacitance between the capacitor terminals.

In at least one example, combiner 310/104 is fabricated in a package substrate of a packaged integrated circuit that includes amplifiers 102 and 103 and transmit circuit 101 of FIG. 1. In at least one example, combiner 310/104 is fabricated on the same semiconductor die that includes amplifiers 102 and 103 and transmit circuit 101 of FIG. 1. In at least one example, combiner 310/104 is external to a packaged integrated circuit that includes amplifiers 102 and 103 and transmit circuit 101 of FIG. 1. In such examples, combiner 310/104 can be a discrete component on a circuit board and is electrically coupled to amplifiers 102 and 103 via the circuit board.

In at least one example, one or more of first, second, third, and fourth capacitors 701, 702, 703, and 704, respectively, and/or first and second capacitors 724 and 713 are on-die capacitors (e.g., on the same semiconductor die that includes amplifiers 102 and 103 and transmit circuit 101 of FIG. 1). In at least one example, one or more of first, second, third, and fourth capacitors 701, 702, 703, and 704, respectively, and/or first and second capacitors 724 and 713 are within an integrated circuit package. In at least one example, one or more of first, second, third, and fourth capacitors 701, 702, 703, and 704, respectively, and/or first and second capacitors 724 and 713 are off-chip capacitors and are external to the packaged integrated circuit that includes amplifiers 102 and 103 and transmit circuit 101 of FIG. 1.

The quadrature hybrid coupler of FIGS. 6 and 7 can have a smaller footprint than coupler based on transmission lines having similar properties. In some examples, a quadrature hybrid coupler including an 8-shaped transformer can have a size of 190 μm×192 μm for combining signals at 50 GHz. In contrast, a transmission line for providing 90 degree phase shift at 50 GHz has a length of about 750 μm (6000 μm/4/sqrt(4)) and a width of about 20 μm. In a case where a coupler includes multiple transmission lines, the total length of the transmission lines will be in the multiple of 750 μm, which occurs a much larger area than a quadrature hybrid coupler including an 8-shaped transformer.

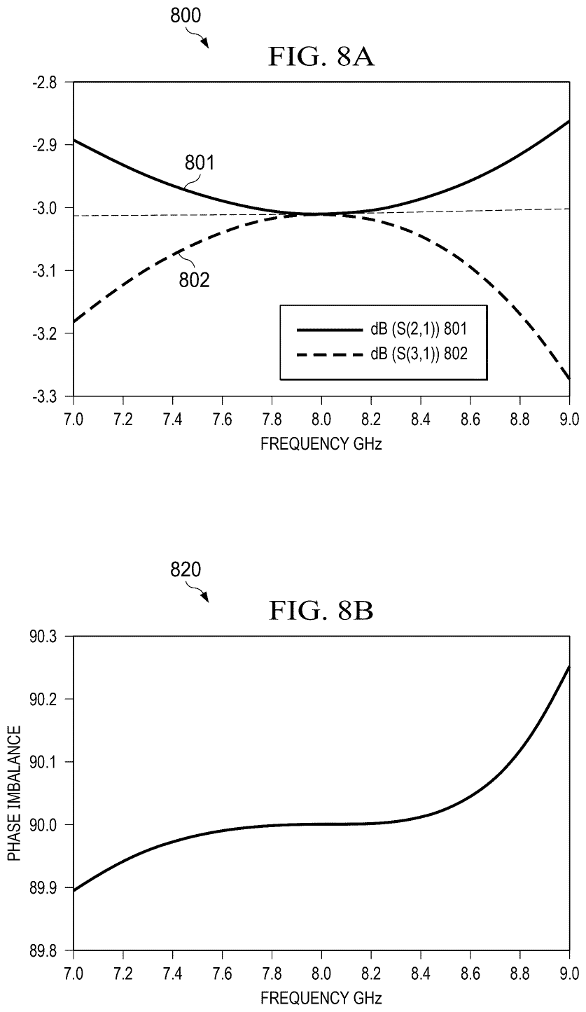

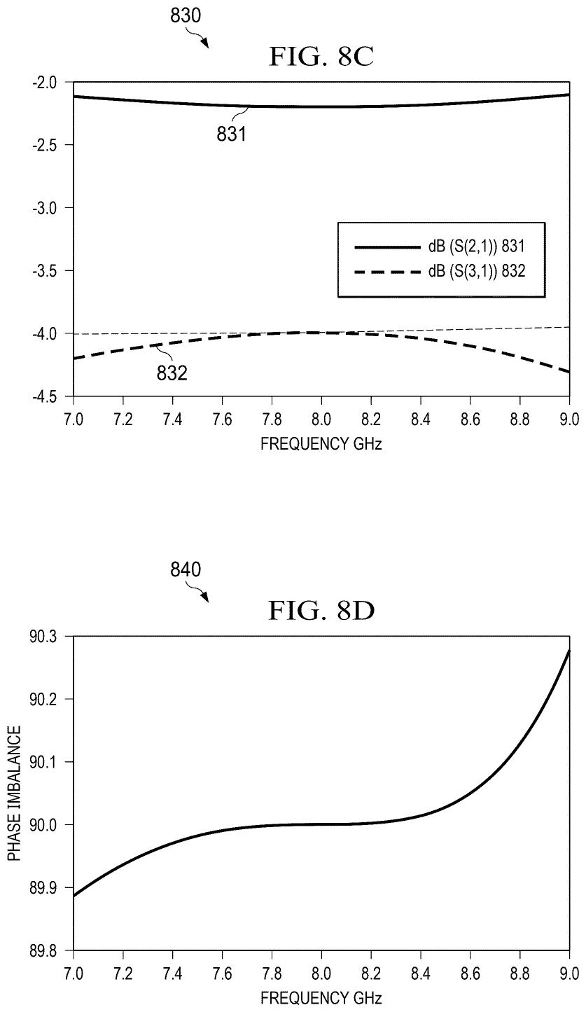

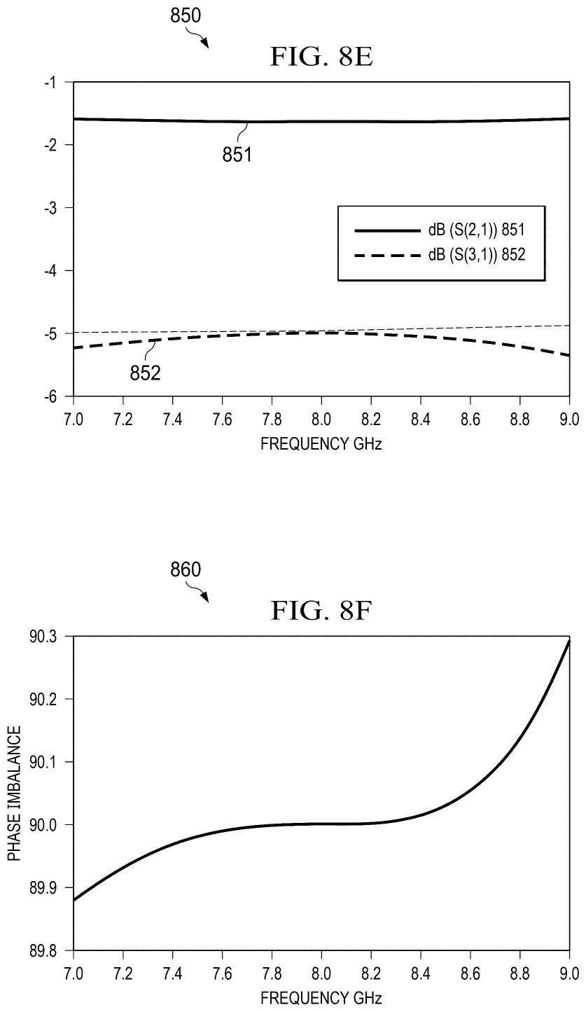

FIGS. 8A-B are plots 800 and 820 showing a first coupling factor and associated phase imbalance as a function of frequency, respectively, in accordance with at least some examples. FIGS. 8C-D are plots 830 and 840 showing a second coupling factor and associated phase imbalance as a function of frequency, respectively, in accordance with at least some examples. FIGS. 8E-F are plots 850 and 860 showing a third coupling factor and associated phase imbalance as a function of frequency, respectively, in accordance with at least some examples. These plots show the effects of changing or adjusting coupling coefficients k between windings or coils 610a and 610b, while maintaining broadband operation as indicated by the phase imbalance. For instance, the scattering parameters S21 and S31 as indicated by waveforms 801 and 802 spread apart as indicated by waveforms 831 and 832, and by waveforms 851 and 852 by reducing the coupling coefficient k. Here, S31 is 20 Log 10(k).

S31 is the scattering parameter between first amplifier 102 and load 105 from couple port 303 and reference port 301. S21 is the scattering parameter between second amplifier 103 and load 105 from through port 302 to reference port 301. By adjusting the equivalent power ratio between first amplifier 102 and second amplifier 103, together with the correct turn-on sequence and current profile from the two amplifiers, each amplifier sees a load modulation trajectory and the whole amplifier can collectively operate at a different back-off efficiency enhancement point. This allows for an equivalently stronger second amplifier 103 to enable deeper back-off enhancement, in accordance with at least one example. At least one example uses a quadrature hybrid coupler to control the relative strength of first amplifier 102 and second amplifier 103. In at least one example, selecting a smaller coupling coefficient k (between coils of a transformer of the quadrature hybrid coupler) allows to couple more energy from the side or port coupled to second amplifier 103 to the output (or make second amplifier 103 stronger), therefore enabling a deeper back-off.

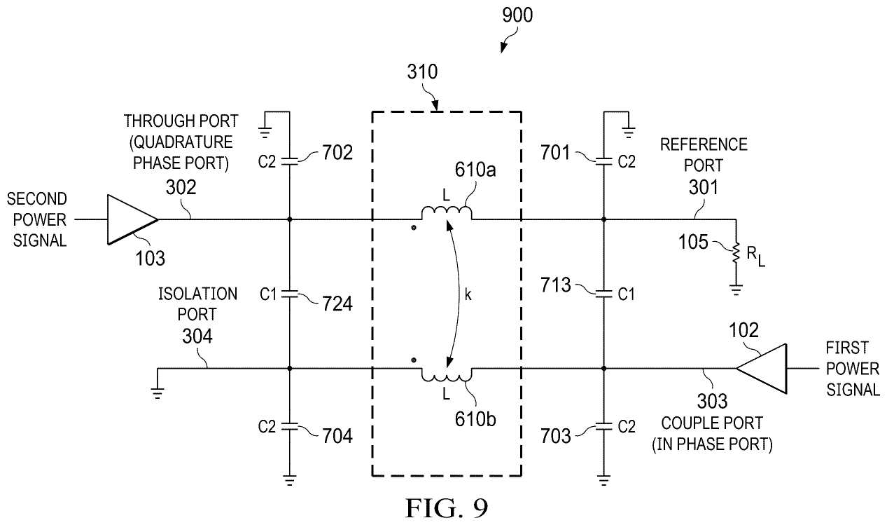

FIG. 9 is a schematic of a power amplifier 900 with a transformer coupler and capacitors at the ports, in accordance with at least one example. Here, connections of the ports to circuit 700 are illustrated. Power amplifier 900 can be an example of power amplifier 100 of FIG. 1, and combiner 310 can be an example of combiner 104 of FIG. 1. In at least one example, reference port 301 is coupled to load 105 (modeled as a resistor R_{L}), first amplifier 102 is coupled to couple port 303, second amplifier 103 is coupled to through port 302, and isolation port 304 is coupled to ground. In at least one example, first amplifier 102 and second amplifier 103 have programmable or adjustable sizes. For instance, transistors may be used to add more width to a transistor unit by turning on/off transistors coupled in parallel, and thus modifying output power of the transistor unit.

In at least one example, the back-off power depth (e.g., −6 dB, −9.5 dB, −11 dB, etc.), is a function of power or current drive of first amplifier 102 (Ifaₘₐₓ) and second amplifier 103 (Isaₘₐₓ). In at least one example, second amplifier 103 provides a higher output power than first amplifier 102. In at least one example, the back-off power depth (e.g., −6 dB, −9.5 dB, −11 dB, etc.) is a function of power supply voltages for first amplifier 102 (Vdd_{fa}) and second amplifier 103 (Vddₛₐ). In at least one example, the coupling coefficient k is proportional to back-off power. In at least one example, capacitance C1 of first and second coupling capacitors 713 and 724, respectively, are inversely proportional to a load impedance of load 105, and a function of back-off power. In at least one example, capacitance C2 of first, second, third, and fourth, capacitors 701, 702, 703, and 704, respectively, are inversely proportional to the load impedance of load 105, and a function of back-off power. In at least one example, the inductance L1 and L2 of windings or coils 610a and 610b, respectively, are proportional to the load impedance of load 105 and inversely proportional to the back-off power.

Table 1 illustrates the various parameters that impact back-off level for power amplifier 900 when impedance of load 105 is 50 Ohms and center of operating frequency is 10 GHz, in accordance with one example.

TABLE 1

| | | Coupling | K of 1:1 | | | |
|---|---|---|---|---|---|---|
| Back-off level (dB) | $\frac{{Ifa}_{m ax}}{{Isa}_{maz}} = \frac{{Vdd}_{fa}}{{Vdd}_{sa}}$ | Factor (dB) | trans- former | L (nH) | C1 (pF) | C2 (pF) |
| −7 | 1.113 | −3.5 | 0.668 | 1.070 | 0.286 | 0.149 |
| −10 | 1.47 | −5 | 0.562 | 0.962 | 0.216 | 0.168 |

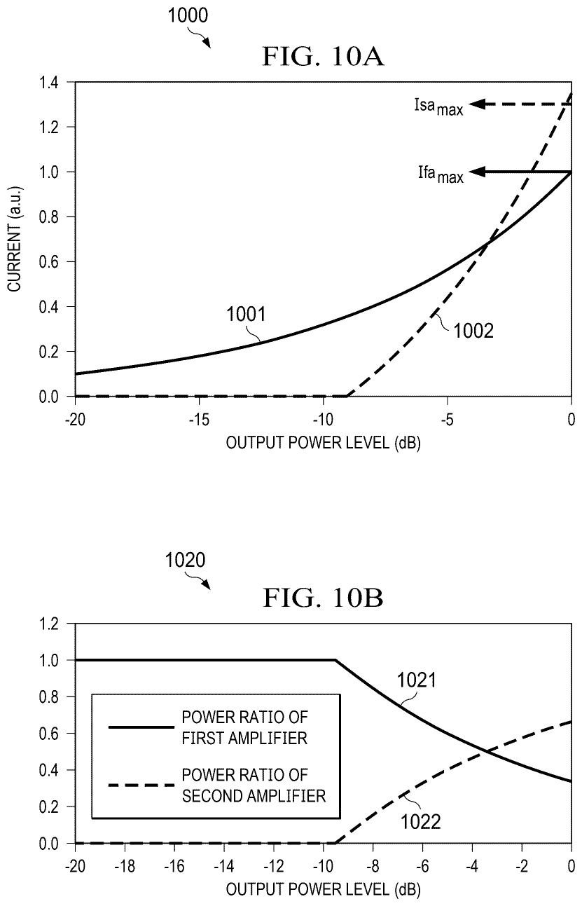

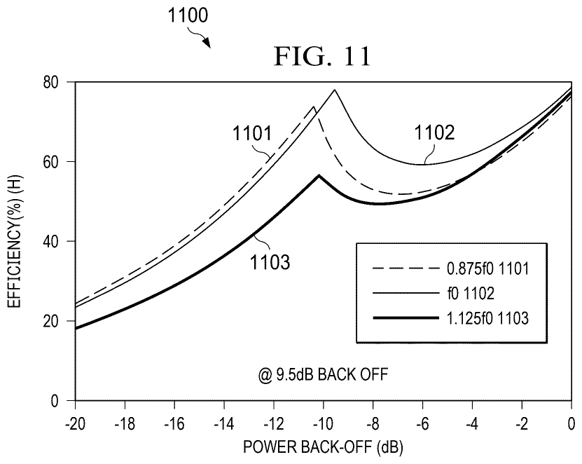

FIG. 10A is a plot 1000 showing current profiles of first amplifier 102 (e.g., a main amplifier) and second amplifier 103 (e.g., an auxiliary amplifier) of power amplifier 900 as a function of back-off power, in accordance with at least one example. Here, x-axis is output power level for a Doherty PA and y-axis is output current for an amplifier. As discussed herein, first amplifier 102 and second amplifier 103 are asymmetrical amplifiers where second amplifier 103 is configured to provide a higher output power at saturation than first amplifier 102. Initially, first amplifier 102 turns on and amplifies a first signal (which is split from an input signal). This is indicated by current profile 1001 of first amplifier 102. First amplifier 102 shows a continuous increase in output current as input power and output power increase. Second amplifier 103 is initially off as indicated by current profile 1002 of second amplifier 103. Second amplifier 103 turns on as the output power level increases above a back-off power level (e.g., −9.5 dB back-off in FIG. 10A or any target back-off level). The current changing slope of second amplifier 103 as it turns on. When the output power level is between the back-off power level (e.g., −9.5 dB in FIG. 10) and around −3.5 dB in FIG. 10A, the output power level of first amplifier 102 is above the output power level of second amplifier 103. At or above −3.5 dB, the output power level of second amplifier 103 exceeds that of first amplifier 102. At a maximum output power level (e.g., 0 dB power), maximum current (Isa_{maz}) of second amplifier 103 is higher than maximum current (Ifaₘₐₓ) of first amplifier 102, and the output power level of second amplifier 103 can be double of first amplifier 103. The maximum current of each amplifier can define the output power level of the amplifier at saturation. In at least one example, the ratio

$$\frac{{Ifa}_{m ax}}{{Isa}_{m az}}$$

is a function of back-off power levels. The joint-function between the current profile and combiner of various examples enhances power amplifier back-off efficiency at back-off power levels.

FIG. 10B is a plot 1020 showing percentage contribution of powers of first amplifier 102 (e.g., a main amplifier) and second amplifier 103 (e.g., an auxiliary amplifier) on the input power as input power or output power increase, in accordance with at least one example. Waveform 1021 is the power ratio of first amplifier 102 (e.g., ratio of power of first amplifier 102 to total power). Waveform 1022 is the power ratio of second amplifier 103 (e.g., ratio of power of second amplifier 103 to total power). In this example, below the 9.5 dB, since second amplifier 103 is off, 100% power comes from first amplifier 102. When second amplifier 103 turns on, the percentage of contribution from first amplifier 102 reduces while the contribution from first amplifier 102 increases. Below the cross point (˜−3.5 dB), first amplifier 102 contributes more power than second amplifier 103. At saturation (0 dB back-off), second amplifier 103 contributes ×2 of the power compared to first amplifier 102. This is due to the size difference that allows second amplifier 103 to have a larger saturation power compared to first amplifier 102, in accordance with at least one example.

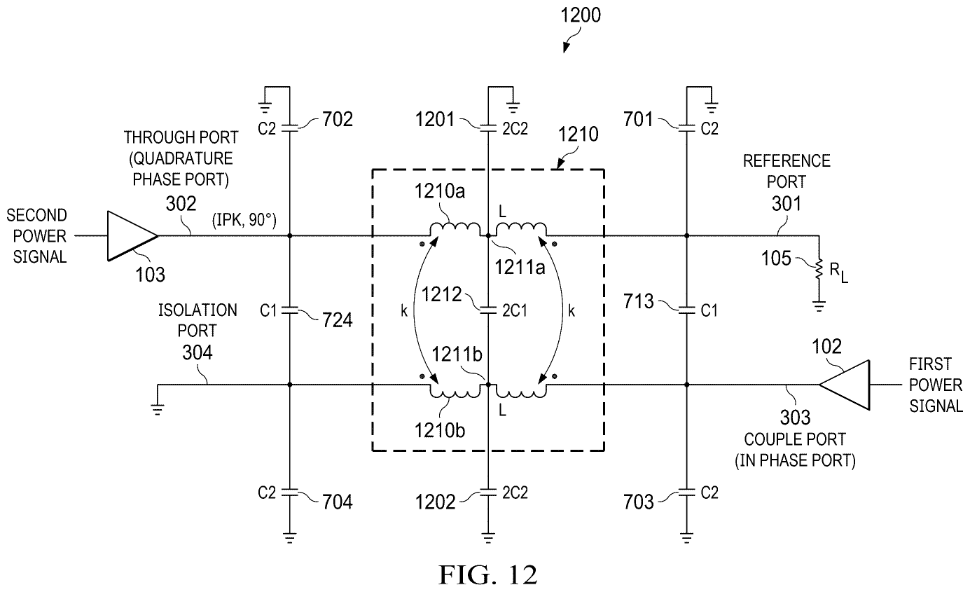

FIG. 11 is a plot 1100 showing efficiency of power amplifier 900 of FIG. 9 as a function of back-off power at different frequencies, in accordance with at least one example. Here, x-axis is back-off power and y-axis is efficiency. Plot 1100 illustrates that efficiency level drops between different operating frequencies 0.875f0, f0, and 1.125f0 as indicated by waveforms 1101, 1102, and 1103, respectively, at the same power back-off level. Here, waveform 1102 is the center operating frequency f0. In this example for power amplifier 900, the efficiency drops from 80% to about 50% as frequency increases for the same back-off power (e.g., −9.5 dB back-off).

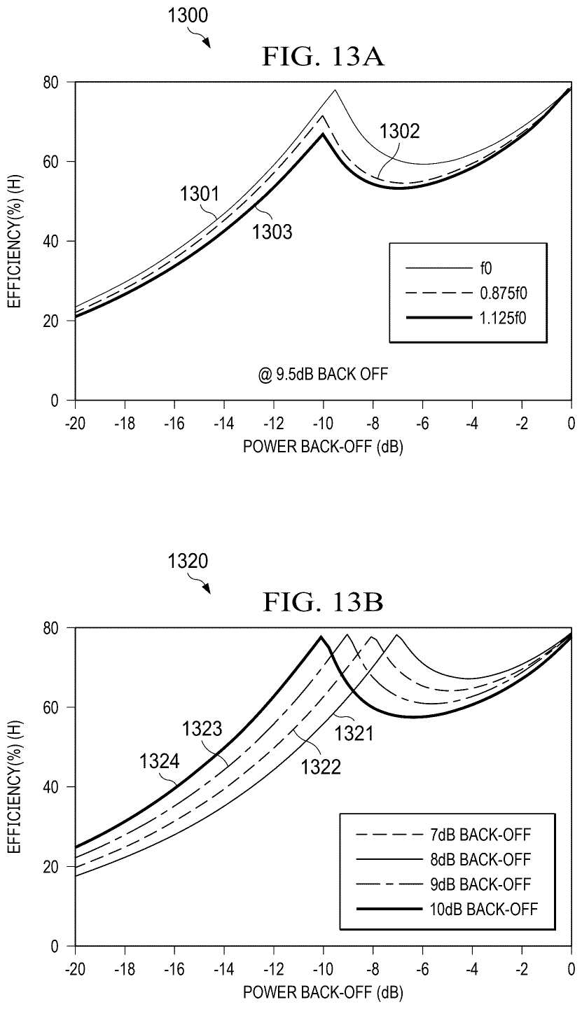

FIG. 12 is a schematic of a power amplifier 1200 with a transformer coupler with center taps and coupling capacitors at the ports and the center taps, in accordance with at least one example. In at least one example, combiner 310 comprises a transformer 1210 with center taps and fifth and sixth capacitors 1201 and 1202 coupled to the center taps. In at least one example, transformer 1210 includes windings or coils 1210a and 1210b. For instance, winding or coil 1210a is a primary coil and winding or coil 1210b is a secondary coil. In at least one example, individual winding coils may be fabricated within a substrate to provide isolation between ports. In at least one example, winding or coil 1210a has a center tap 1211a, and winding or coil 1210b has a center tap 1211b. In at least one example, a third coupling capacitor 1212 of capacitance 2C1 is coupled between winding or coil 1210a and winding or coil 1210b. In at least one example, a fifth capacitor 1201 of capacitance 2C2 is coupled between center tap 1211a and ground. In at least one example, a sixth capacitor 1202 of capacitance 2C2 is coupled between center tap 1211b and ground.

Compared to power amplifier 900, power amplifier 1200 provides higher inductance and additional knobs in the forms of fifth capacitor 1201, sixth capacitor 1202, and third coupling capacitor 1212 to achieved deeper backoff at higher efficiency.

Table 2 illustrates the various parameters that impact back-off level for power amplifier 1200 when impedance of load 105 is 50 Ohms and center of operating frequency is 10 GHz, in accordance with one example.

TABLE 2

| | | Coupling | K of 1:1 | | | |
|---|---|---|---|---|---|---|
| Back-off level (dB) | $\frac{{Ifa}_{m ax}}{{Isa}_{maz}} = \frac{{Vdd}_{fa}}{{Vdd}_{sa}}$ | Factor (dB) | trans- former | L (nH) | C1 (pF) | C2 (pF) |
| −7 | 1.113 | -3.5 | 0.668 | 1.5 | 0.118 | 0.059 |
| −10 | 1.47 | -5 | 0.562 | 1.36 | 0.09 | 0.07 |

Transformer 1210 can be considered as a cascade of two combiners such as combiner 310 and the values for inductances and capacitances for the transformer network may be selected according to a desired back-off level and bandwidth. In at least one example, multiple stages of such combiners may be cascaded to realize a higher order power amplifier with broader bandwidth. In at least one example, between each stage of cascading combiners, a coupling capacitor (e.g., third coupling capacitor 1212) and associated capacitors (e.g., fifth and sixth capacitors 1201 and 1202, respectively) are coupled between stages of cascading combiners and ground.

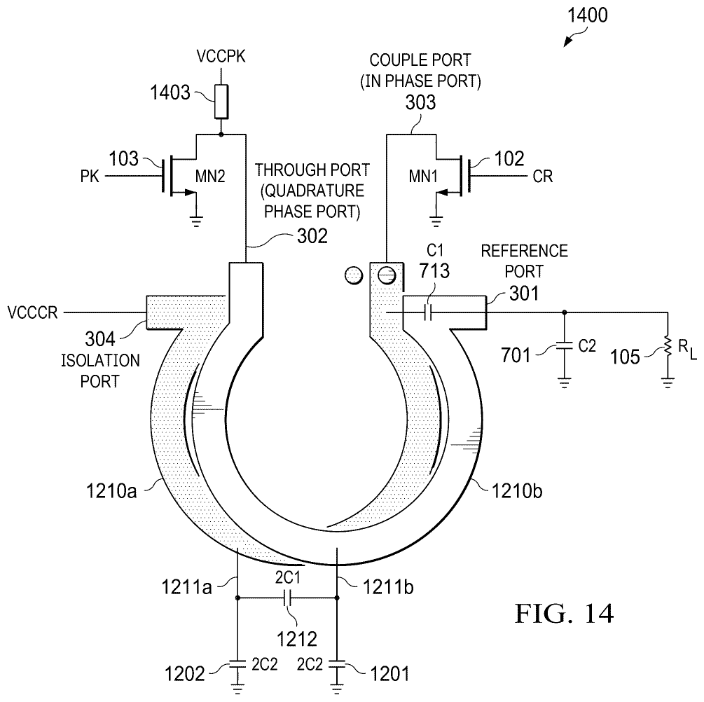

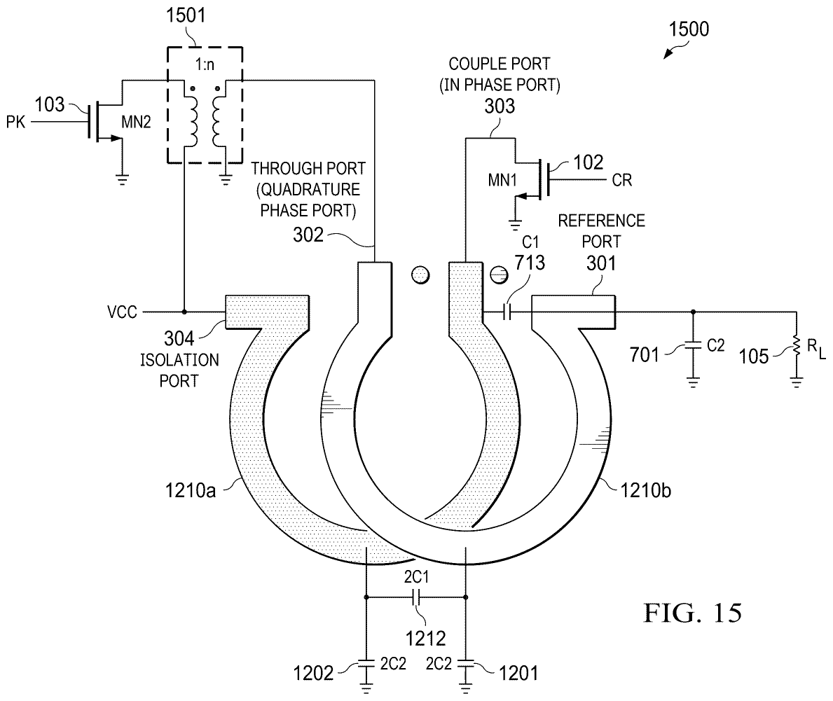

FIG. 13A is a plot 1300 showing efficiency of the power amplifier of FIG. 12 as a function of back-off power, in accordance with at least one example. Compared to plot 1100, the efficiency for power amplifier 1200 is largely flat over frequencies as indicated by waveforms 1301, 1302, and 1303. Here, waveform 1302 is the center operating frequency f0. For instance, the efficiency drops from 80% to about 70% as frequency increases for the same back-off power (e.g., −9.5 dB back-off). Power amplifier 1200 can be scaled to any operating frequency.

FIG. 13B is a plot 1320 showing efficiency of the power amplifier of FIG. 12 for different back-off powers at a center frequency f0, in accordance with at least one example. Plot 1320 shows broadband operation of power amplifier 1200 for different back-off power levels. For instance, waveform 1321 corresponds to −7 dB back-off, waveform 1322 corresponds to −8 dB back-off, waveform 1323 corresponds to −9 dB back-off, and waveform 1324 corresponds to −10 dB back-off. Here, efficiency of 80% is achieved across the various back-off power levels by power amplifier 1200.

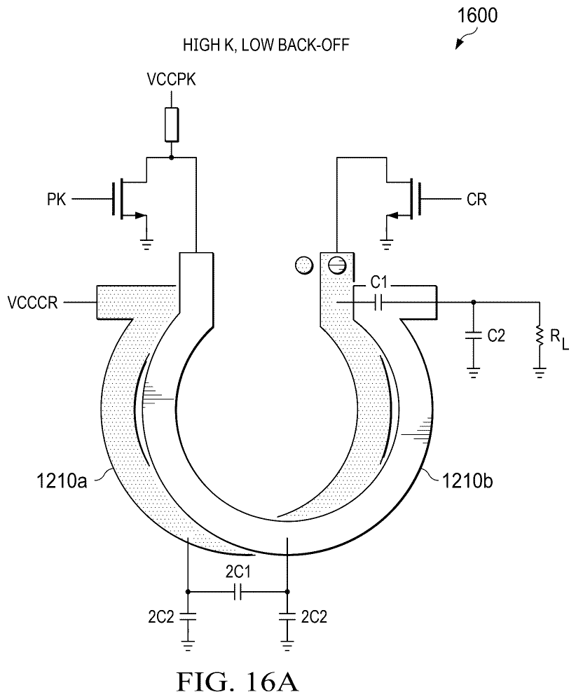

FIG. 14 is a schematic of a power amplifier 1400 with a transformer coupler with center taps and coupling capacitors at the ports and the center taps, in accordance with at least one example. Power amplifier 1400 is an implementation of power amplifier 1200 in accordance with at least one example. In at least one example, winding or coil 1210a is a horse-shoe shaped coil in a first layer of a dielectric, and winding or coil 1210a is another horse-shoe shaped coil in a second layer of the dielectric. While power amplifier 1400 illustrates horse-shoe shaped coils, any shape can be used for windings or coils 1210a and 1210b. In at least one example, windings or coils 1210a and 1210b have symmetrical shapes with center taps as point of symmetries. For instance, winding or coil 1210a has a center tap 1211a, which is also a point of symmetry and winding or coil 1210b has a center tap 1211b.

In at least one example, first amplifier 102 comprises an n-type transistor MN1 with a source terminal coupled to ground and a drain terminal coupled to couple port 303 of winding or coil 1210a. In at least one example, a gate terminal of n-type transistor MN1 is controllable by the first signal. In at least one example, isolation port 304 of winding or coil 1210a is coupled to first power supply VCCCR. In at least one example, second amplifier 103 comprises an n-type transistor MN2 with a source terminal coupled to ground and a drain terminal coupled to couple port 303 of winding or coil 1210b and a bias line 1403, which in turn is coupled to a second power supply VCCPK. In at least one example, a gate terminal of n-type transistor MN2 is controllable by the second signal. In at least one example, to achieve a back-off power of −9.5 dB, a voltage ratio of VCCPK to VCCCR is 1.4.

As discussed herein, first amplifier 102 (e.g., a main amplifier) and second amplifier 103 (e.g., an auxiliary amplifier) are asymmetrical amplifiers. In at least one example, first amplifier 102 is a class AB amplifier, and second amplifier 103 is a class C amplifier. First amplifier 102 receives the first signal at the gate terminal of transistor MN1 and is coupled to couple port 303 of quadrature hybrid combiner 1210. In at least one example, the second signal is provided to the gate terminal of transistor MN2 of second amplifier 103, which is coupled to through port 302 of quadrature hybrid combiner 1210. In at least one example, first amplifier 102 is configured to provide a first output power level at saturation, second amplifier 103 is configured to provide a second output power level at saturation, and the second power level is higher than the first power level. In at least one example, first amplifier 102 operates by amplifying the first signal, while second amplifier 103 is off. Upon the input power level crossing a power threshold (or the output power level crossing a back-off power threshold), second amplifier 103 turns on and amplifies the second signal, while first amplifier 102 continues to operate. The outputs of first and second amplifiers 102 and 103, respectively, are combined by quadrature hybrid combiner 1210 and provided to reference port 301 where load 105 is coupled.

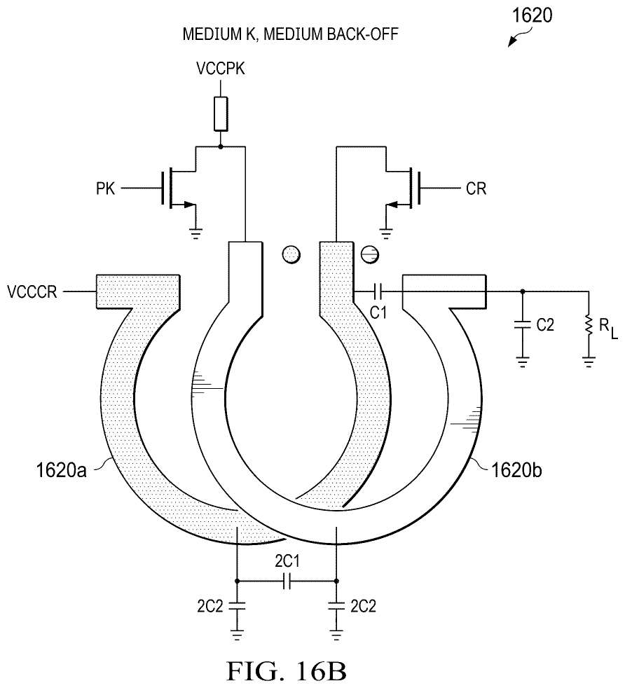

FIG. 15 is a schematic of a power amplifier 1500 with a transformer coupler with center taps and coupling capacitors at the ports and the center taps, and with a 1:n transformer, in accordance with at least one example. In at least one example, power amplifier 1400 uses different supply voltages VCCCR and VCCPK for first amplifier 102 and second amplifier 103, respectively. In at least one example, a single supply VCC can be used for first amplifier 102 and second amplifier 103 instead of different supply voltages VCCCR and VCCPK, respectively, by using a 1:n transformer 1501 coupled to second amplifier 103, where ‘n’ is a function of back-off levels, which may be an integer or fraction. In at least one example, 1:n transformer 1501 is used to supply power to first amplifier 103. In at least one example, turn ‘n’ of transformer 1501 is a function of back-off power level. In at least one example, 1:n transformer 1501 provides the voltage multiplication from supply voltage VCC instead of using two separate supply voltages VCCCR and VCCPK. In at least one example, VCC is the lower of supply voltages VCCCR and VCCPK.

In at least one example, the drain terminal of second amplifier 103 is coupled to a first terminal of a first coil or inductor of 1:n transformer 1501, and second terminal of the first coil or inductor of 1:n transformer 1501 is coupled to power supply rail VCC, which in turn is coupled to isolation port 304. In at least one example, a first terminal of a second coil or inductor of 1:n transformer 1501 is coupled to through port 302 while a second terminal of the second coil or inductor of 1:n transformer 1501 is coupled to ground, where a ratio of the number of coils of the first coil or inductor to the second coil or inductor is 1 to n.

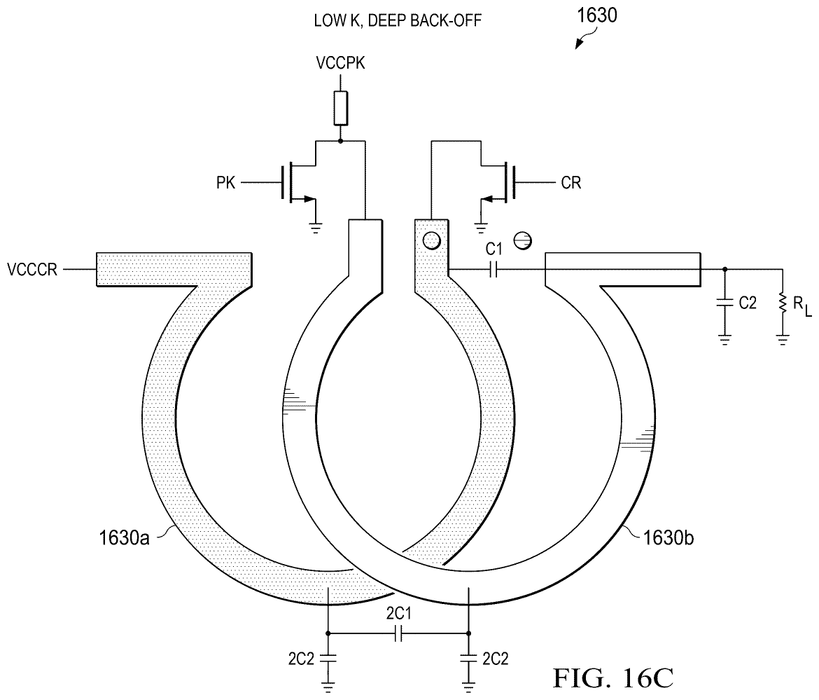

FIG. 16A-C are schematics of power amplifiers 1600, 1620, and 1630, respectively, with different coupling coefficients, transformer sizes, and back-off powers, in accordance with at least one example. In at least one example, deeper back-off power is achieved by reducing the coupling coefficient k. In at last one example, coupling coefficient k is reduced by reducing the overlapping area between the windings or coils. Here, windings or coils 1210a and 1210b have the most overlap and thus higher coupling coefficient k and lower back-off power, windings or coils 1620a and 1620b have the lesser overlap and thus lesser coupling coefficient k and higher (e.g., deeper) back-off power than that of FIG. 16A, and windings or coils 1630a and 1630b have the lesser overlap and thus lesser coupling coefficient k and higher (e.g., deeper) back-off power than that of FIG. 16B. While power amplifiers 1600, 1620, and 1630 are illustrated with reference to the example of power amplifier of FIG. 14, the same concept applies to power amplifier of FIG. 15.

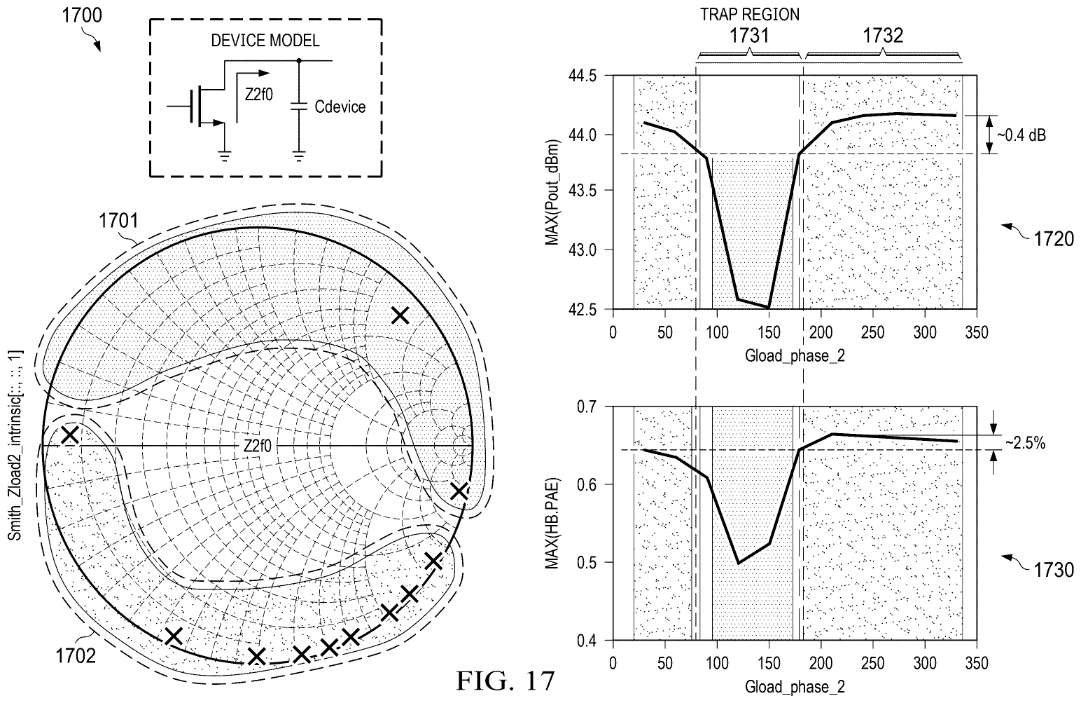

FIG. 17 is a set of plots 1700, 1720, and 1730 that show the influence of second harmonic impedance that load the device model shown in the inset. To get better output power and efficiency performance, impedance Z2f0 is desired to be in the capacitive region, in accordance with at least one example. Utilizing second harmonics at drain terminal of first and second amplifier transistors MN1 and MN2, respectively, is an effective way of increasing power efficiency. This is achieved by configuring waveforms to reduce the alignment between current and voltage waveforms, in accordance with at least one example. For a Gallium Nitride (GaN) power device, a desired intrinsic second harmonic impedance for high efficiency lies in a capacitive region of the Smith chart. While a traditional matching network or combiner may need to add additional harmonic tanks or filtering network to achieve desired harmonic load of the transistor, the quadrature hybrid combiner of various examples naturally allows proper capacitive second harmonic termination without manually adding additional harmonic networks (e.g., using intrinsic L-C lumped configuration of the 90 hybrid).

Plot 1700 is a Smith chart with an inductive region 1701 and a capacitive region 1702. Plot 1720 shows an output power of a GaN transistor as a function of phase of the second harmonic impedance Z2f0. The second harmonic impedance changes across the outer edge of the Smith chart of plot 1700 so the phase change of the second harmonic impedance changes from 0 to 360 degrees. Plot 1730 shows the GaN transistor power added efficiency as a function of the phase of the second harmonic impedance. In at least one example, for both output power and efficiency, there is a trap region 1731 that may be undesirable because trap region 1731 degrades efficiency by 15% and power by 1.5 dB. Trap region 1731 corresponds to inductive region 1701 of the Smith chart of plot 1700. In at least one example, second harmonic impedance phase 1732 is desirable and falls in capacitive region 1702.

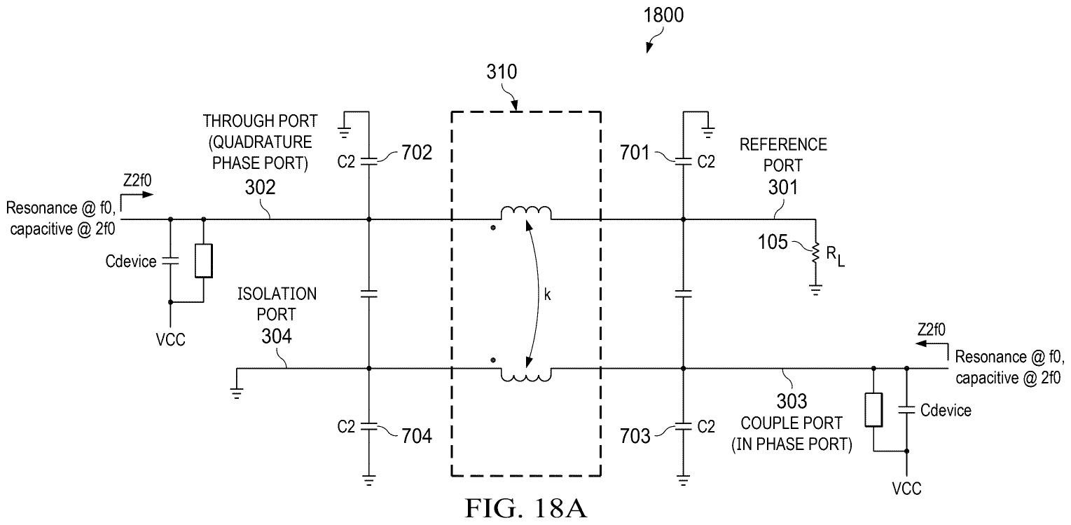

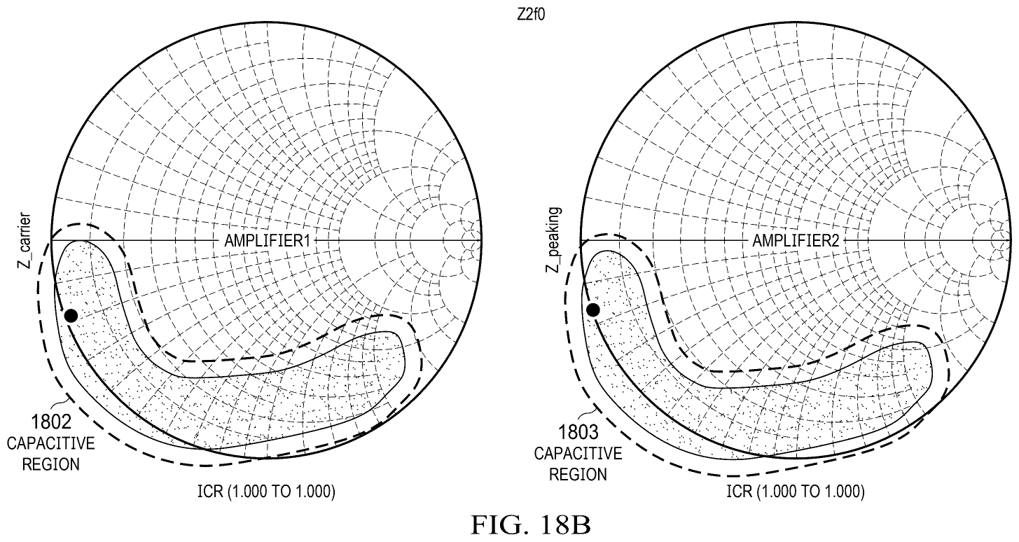

FIG. 18A is a schematic showing a setup 1800 for determining input second harmonic impedance Z2f0 at through port 302 and couple port 303, in accordance with at least one example. The 2nd harmonic input impedances Z2f0 are load impedances of first and second amplifier transistors MN1 and MN2. FIG. 18B is a set of Smith charts 1802 and 1803 showing load impedances (Z2f0) at second harmonic frequencies for the amplifiers connected to couple port 303 and through port 302, respectively, of the power amplifier, in accordance with at least one example. Smith charts 1802 and 1803 show the input impedance of a 90-hybrid combiner. Note, the input impedance of the quadrature hybrid coupler is the load of the device. At second harmonic this impedance Z2f0 is in the capacitive region of the Smith charts for both amplifiers. As discussed with reference to FIG. 17, the second harmonic load impedance of transistors MN1 and MN2 should be in the capacitive region, and combiner network of setup 1800 naturally provides the desired second harmonic impedance for transistors MN1 and MN2.

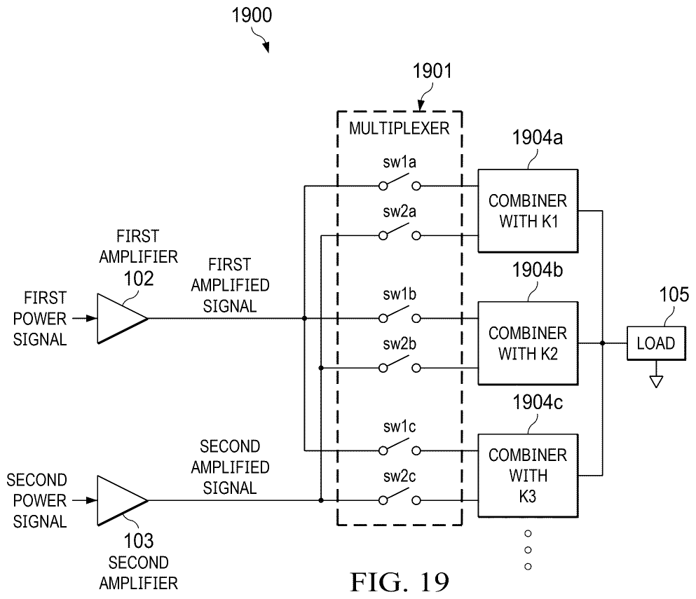

FIG. 19 is a schematic of a power amplifier 1900 with selectable combiners, in accordance with at least one example. In at least one example, power amplifier 1900 comprises multiplexer 1901 and a plurality of combiners (e.g., combiners 1904a, 1904b, 1904c, . . . ). In at least one example, multiplexer 1901 includes pairs switches such as switches sw1a, sw2a, sw1b, sw2b, sw1c, sw2c, and so on. In at least one example, the switches are implemented as transistors. In at least one example, gates of the transistors are controlled by control signals generated from an on-die or an off-die logic. In at least one example, one switch from a pair of switches is coupled to couple port 303 and an output of first amplifier 102, while another switch from the pair of switches is coupled to through port 302 and second amplifier 103. In at least one example, depending on the depth of a target back-off power, a combiner with desired coupling coefficient k is selected and coupled to first amplifier 102 and second amplifier 103.

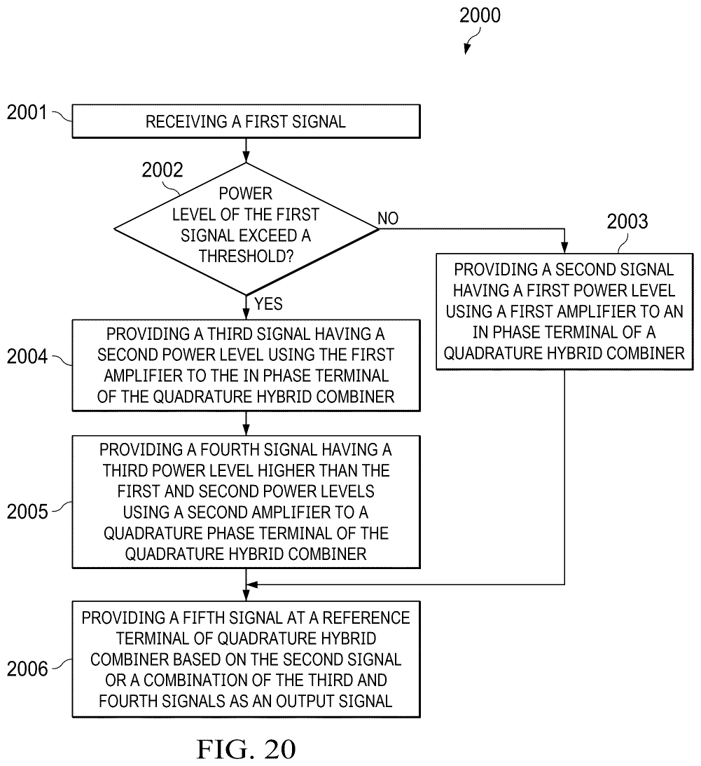

FIG. 20 is a flowchart 2000 of a method of operating the power amplifier, in accordance with at least one example. While various blocks are shown in a particular order, the order may be modified. For example, some blocks may be performed before others, while some blocks may be performed simultaneously.

At block 2001, a quadrature hybrid combiner (e.g., combiners 310, 1210, or other combiners discussed herein) receives a first signal. At block 2002, a determination is made whether the power level of the first signal exceeds a threshold (e.g., a back-off level target). If the power level of the first signal does not exceed the threshold, at block 2003, a second signal of a first power level is provided by first amplifier 102 to couple port 303 (e.g., in phase port) of the quadrature hybrid combiner. If the power level of the first signal exceeds the threshold, at block 2004, a third signal is provided by first amplifier 102 to couple port 303 (e.g., in phase port) of the quadrature hybrid combiner. At block 2005, a fourth signal is provided to the quadrature hybrid combiner using second amplifier 103. The power level of the fourth signal is higher than that of the third signal. At block 2006, a fifth signal is provided at reference port 301 based on the second signal or a combination of the third and fourth signals as an output signal to load 105.

### INVENTORS, YOU CAN SKIP THIS SECTION OF EXAMPLES

The following are additional examples provided in view of the above-described implementations. Here, one or more features of example, in isolation or in combination, can be combined with one or more features of one or more other examples to form further examples also falling within the scope of the disclosure. As such, one implementation can be combined with one or more other implementations without changing the scope of disclosure.

Example 1 is an apparatus comprising: a first amplifier (CR) having a first amplifier output and configured to provide a first signal having a first power level at the first amplifier output; a second amplifier (PK) having a second amplifier output and configured to provide a second signal having a second power level at the second amplifier output, the second power level being higher than the first power level; and a combiner circuit having a quadrature-phase terminal (thru), an in phase terminal (couple), a reference terminal (reference), and an isolation terminal (isolation), the in phase terminal coupled to the first amplifier output, the quadrature phase terminal coupled to the second amplifier output, the reference terminal coupled to a combiner output, and the isolation terminal coupled to a direct current (DC) voltage source.

Example 2 is an apparatus according to any example herein, in particular example 1, wherein the combiner circuit includes a quadrature hybrid combiner.

Example 3 is an apparatus according to any example herein, in particular example 1, wherein the combiner circuit includes a first coil electrically coupled between the reference terminal and the quadrature phase terminal and a second coil electrically coupled between the in phase terminal and the isolation terminal, the first coil being magnetically coupled to the second coil.

Example 4 is an apparatus according to any example herein, in particular example 3, further comprising: a first capacitor coupled between the in phase terminal and a DC terminal; a second capacitor coupled between the quadrature phase terminal and the DC terminal; a third capacitor coupled between the reference terminal and the DC terminal; a fourth capacitor coupled between the isolation terminal and the DC terminal; a fifth capacitor coupled between the quadrature phase terminal and the isolation terminal; and a sixth capacitor coupled between the in-phase terminal and the reference terminal.

Example 5 is an apparatus according to any example herein, in particular example 4, wherein the first, second, third, fourth, fifth, and sixth capacitors are on-chip capacitors.

Example 6 is an apparatus according to any example herein, in particular example 4, wherein the first, second, third, fourth, fifth, and sixth capacitors are off-chip capacitors.

Example 7 is an apparatus according to any example herein, in particular example 3, wherein the first coil has a first center tap terminal, the second coil has a second center tap terminal, and the apparatus further comprises: a first capacitor coupled between the in-phase terminal and a DC terminal; a second capacitor coupled between the quadrature phase terminal and the DC terminal; a third capacitor coupled between the reference terminal and the DC terminal; a fourth capacitor coupled between the isolation terminal and the DC terminal; a fifth capacitor coupled between the first center tap terminal and the DC terminal; a sixth capacitor coupled between the second center tap terminal and the DC terminal; a seventh capacitor coupled between the quadrature phase terminal and the isolation terminal; an eighth capacitor coupled between the in-phase terminal and the reference terminal; and a ninth capacitor coupled between the first and second center tap terminals.

Example 8 is an apparatus according to any example herein, in particular example 7, wherein the first, second, third, fourth, fifth, and sixth capacitors are on-chip capacitors.

Example 9 is an apparatus according to any example herein, in particular example 7, wherein the first, second, third, fourth, fifth, and sixth capacitors are off-chip capacitors.

Example 10 is an apparatus according to any example herein, in particular example 3, wherein the first and second coils are part of a transformer.

Example 11 is an apparatus according to any example herein, in particular example 3, wherein an inductance of each of the first and second coils is based on a target back-off level at the combiner output, a load impedance at the combiner output, and an operation frequency of the apparatus.

Example 12 is an apparatus according to any example herein, in particular example 1, wherein the combiner circuit includes at least one of: a branch line hybrid coupler or a lange hybrid coupler.

Example 13 is an apparatus according to any example herein, in particular example 2, wherein a coupling factor of the quadrature hybrid combiner is based on a target power back-off level at the combiner output.

Example 14 is an apparatus according to any example herein, in particular example 1, wherein the second amplifier is configured to have a higher output power level at saturation than the first amplifier.

Example 15 is an apparatus according to any example herein, in particular example 1, wherein the combiner circuit is a first combiner circuit, the quadrature phase terminal is a first quadrature phase terminal, the in-phase terminal is a first in phase terminal, the reference terminal is a first reference terminal, and the isolation terminal is a first isolation terminal; wherein the apparatus further comprises: a second combiner circuit having a second quadrature phase terminal, a second in phase terminal, a second reference terminal, and a second isolation terminal, the second reference terminal coupled to the combiner output, and the second isolation terminal coupled to the DC voltage source; a first switch network coupled between the first amplifier output and the first and second in phase terminals; and a second switch network coupled between the second amplifier output and the first and second quadrature phase terminals.

Example 16 is an apparatus according to any example herein, in particular example 1, wherein the combiner circuit, the first amplifier, and the second amplifier are part of an integrated circuit (IC).

Example 17 is apparatus according to any example herein, in particular example 1 further comprises a transformer having a first coil and a second coil, wherein a first terminal of the first coil is coupled to the DC voltage source, wherein the quadrature phase terminal is coupled to the second amplifier output via the transformer, wherein a second terminal of the first coil is coupled to the second amplifier output, wherein a first terminal of the second coil is coupled to ground, and wherein the second terminal of the second coil is coupled to the quadrature phase terminal.

Example 18 is apparatus according to any example herein, in particular example 17, wherein the first coil and the second coil have a same number of turns.

Example 19 is apparatus according to any example herein, in particular example 17, wherein the first coil and the second coil have a different number of turns.

Example 20 is apparatus according to any example herein, in particular example 17, wherein the first coil has a first number of turns, wherein the second coil has a second number of turns, wherein a ratio of the first number of turns to the second number of turns is a function of a back-off power level.

Example 21 is an apparatus comprising: a transmit circuit having a transmit input, a first transmit output, and a second transmit output; a first amplifier having a first amplifier input and a first amplifier output, the first amplifier input coupled to the first transmit output; a second amplifier having a second amplifier input and a second amplifier output, the second amplifier input coupled to the second transmit output, and the first and second amplifiers having different power levels at saturation; and a quadrature hybrid combiner coupled between the first and second amplifier outputs and a combiner output.

Example 22 is an apparatus according to any example herein, in particular example 21, wherein the quadrature hybrid combiner includes a quadrature phase terminal (thru), an in phase terminal (couple), a reference terminal (reference), and an isolation terminal (isolation), the in phase terminal coupled to the first amplifier output, the quadrature phase terminal coupled to the second amplifier output, the reference terminal coupled to a quadrature hybrid combiner output, and the isolation terminal coupled to a direct current (DC) voltage source.

Example 23 is an apparatus according to any example herein, in particular example 22, wherein the quadrature hybrid combiner includes a first coil electrically coupled between the reference terminal and the quadrature phase terminal and a second coil electrically coupled between the in-phase terminal and the isolation terminal, the first coil being magnetically coupled to the second coil.

Example 24 is an apparatus according to any example herein, in particular example 23, further comprising: a first capacitor coupled between the in-phase terminal and a DC terminal; a second capacitor coupled between the quadrature phase terminal and the DC terminal; a third capacitor coupled between the reference terminal and the DC terminal; a fourth capacitor coupled between the isolation terminal and the DC terminal; a fifth capacitor coupled between the quadrature phase terminal and the isolation terminal; and a sixth capacitor coupled between the in-phase terminal and the reference terminal.

Example 25 is an apparatus according to any example herein, in particular example 24, wherein the first, second, third, fourth, fifth, and sixth capacitors are on-chip capacitors.

Example 26 is an apparatus according to any example herein, in particular example 24, wherein the first, second, third, fourth, fifth, and sixth capacitors are off-chip capacitors.

Example 27 is an apparatus according to any example herein, in particular example 23, wherein the first coil has a first center tap terminal, the second coil has a second center tap terminal, and the apparatus further comprises: a first capacitor coupled between the in-phase terminal and a DC terminal; a second capacitor coupled between the quadrature phase terminal and the DC terminal; a third capacitor coupled between the reference terminal and the DC terminal; a fourth capacitor coupled between the isolation terminal and the DC terminal; a fifth capacitor coupled between the first center tap terminal and the DC terminal; a sixth capacitor coupled between the second center tap terminal and the DC terminal; a seventh capacitor coupled between the quadrature phase terminal and the isolation terminal; an eighth capacitor coupled between the in-phase terminal and the reference terminal; and a ninth capacitor coupled between the first and second center tap terminals.

Example 28 is a method comprising: receiving a first signal; responsive to a power level of the first signal being below a threshold: providing a second signal having a first power level using a first amplifier to an in phase terminal of a quadrature hybrid combiner; responsive to a power level of the first signal being above the threshold: providing a third signal having a second power level using the first amplifier to the in phase terminal; and providing a fourth signal having a third power level higher than the first and second power levels using a second amplifier to a quadrature phase terminal of the quadrature hybrid combiner; and providing a fifth signal at a reference terminal of quadrature hybrid combiner based on the second signal or a combination of the third and fourth signals as an output signal.

Besides what is described herein, various modifications can be made to disclose implementations and implementations thereof without departing from their scope. Therefore, illustrations of implementations herein should be construed as examples, and not restrictive to scope of present disclosure.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In the description and in the claims, the terms “including” and “having” and variants thereof are intended to be inclusive in a manner similar to the term “comprising” unless otherwise noted. In addition, the terms “couple,” “coupled,” or “couples” means an indirect or direct electrical or mechanical connection.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics, or semiconductor component.

A circuit or device that is described herein as including certain components may instead be adapted to be coupled to those components to form the described circuit or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuit. For example, a field effect transistor (“FET”) (such as an n-channel FET (NFET) or a p-channel FET (PFET)), a bipolar junction transistor (BJT-e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN), or a gallium arsenide substrate (GaAs).

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately,” or “substantially” preceding a parameter means being within +/−10 percent of that parameter or, if the parameter is zero, a reasonable range of values around zero.

What is claimed is:

1. An apparatus comprising:
a first amplifier having a first amplifier output and configured to provide a first signal having a first power level at the first amplifier output;
a second amplifier having a second amplifier output and configured to provide a second signal having a second power level at the second amplifier output, the second power level being higher than the first power level; and
a combiner circuit having a quadrature phase terminal, an in phase terminal, a reference terminal, and an isolation terminal, the in phase terminal coupled to the first amplifier output, the quadrature phase terminal coupled to the second amplifier output, the reference terminal coupled to a combiner output, and the isolation terminal coupled to a direct current (DC) voltage source.

2. The apparatus of claim 1, wherein the combiner circuit includes a quadrature hybrid combiner.

3. The apparatus of claim 1, wherein the combiner circuit includes a first coil electrically coupled between the reference terminal and the quadrature phase terminal and a second coil electrically coupled between the in phase terminal and the isolation terminal, the first coil being magnetically coupled to the second coil.

4. The apparatus of claim 3, further comprising:
a first capacitor coupled between the in phase terminal and a DC terminal;
a second capacitor coupled between the quadrature phase terminal and the DC terminal;
a third capacitor coupled between the reference terminal and the DC terminal;
a fourth capacitor coupled between the isolation terminal and the DC terminal;
a fifth capacitor coupled between the quadrature phase terminal and the isolation terminal; and
a sixth capacitor coupled between the in-phase terminal and the reference terminal.

5. The apparatus of claim 4, wherein the first, second, third, fourth, fifth, and sixth capacitors are on-chip capacitors.

6. The apparatus of claim 4, wherein the first, second, third, fourth, fifth, and sixth capacitors are off-chip capacitors.

7. The apparatus of claim 3, wherein the first coil has a first center tap terminal, the second coil has a second center tap terminal, and the apparatus further comprises:
a first capacitor coupled between the in-phase terminal and a DC terminal;
a second capacitor coupled between the quadrature phase terminal and the DC terminal;
a third capacitor coupled between the reference terminal and the DC terminal;
a fourth capacitor coupled between the isolation terminal and the DC terminal;
a fifth capacitor coupled between the first center tap terminal and the DC terminal;
a sixth capacitor coupled between the second center tap terminal and the DC terminal;
a seventh capacitor coupled between the quadrature phase terminal and the isolation terminal;
an eighth capacitor coupled between the in-phase terminal and the reference terminal; and
a ninth capacitor coupled between the first and second center tap terminals.

8. The apparatus of claim 7, wherein the first, second, third, fourth, fifth, and sixth capacitors are on-chip capacitors.

9. The apparatus of claim 7, wherein the first, second, third, fourth, fifth, and sixth capacitors are off-chip capacitors.

10. The apparatus of claim 3, wherein the first and second coils are part of a transformer.

11. The apparatus of claim 3, wherein an inductance of each of the first and second coils is based on a target back-off level at the combiner output, a load impedance at the combiner output, and an operation frequency of the apparatus.

12. The apparatus of claim 1, wherein the combiner circuit includes at least one of: a branch line hybrid coupler or a lange hybrid coupler.

13. The apparatus of claim 2, wherein a coupling factor of the quadrature hybrid combiner is based on a target power back-off level at the combiner output.

14. The apparatus of claim 1, wherein the second amplifier is configured to have a higher output power level at saturation than the first amplifier.

15. The apparatus of claim 1, wherein the combiner circuit is a first combiner circuit, the quadrature phase terminal is a first quadrature phase terminal, the in-phase terminal is a first in phase terminal, the reference terminal is a first reference terminal, and the isolation terminal is a first isolation terminal;
wherein the apparatus further comprises:
a second combiner circuit having a second quadrature phase terminal, a second in phase terminal, a second reference terminal, and a second isolation terminal, the second reference terminal coupled to the combiner output, and the second isolation terminal coupled to the DC voltage source;
a first switch network coupled between the first amplifier output and the first and second in phase terminals; and
a second switch network coupled between the second amplifier output and the first and second quadrature phase terminals.

16. The apparatus of claim 1, wherein the combiner circuit, the first amplifier, and the second amplifier are part of an integrated circuit (IC).

17. The apparatus of claim 1 further comprises a transformer having a first coil and a second coil, wherein a first terminal of the first coil is coupled to the DC voltage source, wherein the quadrature phase terminal is coupled to the second amplifier output via the transformer, wherein a second terminal of the first coil is coupled to the second amplifier output, wherein a first terminal of the second coil is coupled to ground, and wherein the second terminal of the second coil is coupled to the quadrature phase terminal.

18. The apparatus of claim 17, wherein the first coil and the second coil have a same number of turns.

19. The apparatus of claim 17, wherein the first coil and the second coil have a different number of turns.

20. The apparatus of claim 17, wherein the first coil has a first number of turns, wherein the second coil has a second number of turns, wherein a ratio of the first number of turns to the second number of turns is a function of a back-off power level.

21. An apparatus comprising:
a transmit circuit having a transmit input, a first transmit output, and a second transmit output;
a first amplifier having a first amplifier input and a first amplifier output, the first amplifier input coupled to the first transmit output;
a second amplifier having a second amplifier input and a second amplifier output, the second amplifier input coupled to the second transmit output, and the first and second amplifiers having different power levels at saturation; and
a quadrature hybrid combiner coupled between the first and second amplifier outputs and a combiner output.

22. The apparatus of claim 21, wherein the quadrature hybrid combiner includes a quadrature phase terminal, an in phase terminal, a reference terminal, and an isolation terminal, the in phase terminal coupled to the first amplifier output, the quadrature phase terminal coupled to the second amplifier output, the reference terminal coupled to a quadrature hybrid combiner output, and the isolation terminal coupled to a direct current (DC) voltage source.

23. The apparatus of claim 22, wherein the quadrature hybrid combiner includes a first coil electrically coupled between the reference terminal and the quadrature phase terminal and a second coil electrically coupled between the in-phase terminal and the isolation terminal, the first coil being magnetically coupled to the second coil.

24. The apparatus of claim 23, further comprising:
a first capacitor coupled between the in-phase terminal and a DC terminal;
a second capacitor coupled between the quadrature phase terminal and the DC terminal;
a third capacitor coupled between the reference terminal and the DC terminal;
a fourth capacitor coupled between the isolation terminal and the DC terminal;
a fifth capacitor coupled between the quadrature phase terminal and the isolation terminal; and
a sixth capacitor coupled between the in-phase terminal and the reference terminal.

25. The apparatus of claim 23, wherein the first coil has a first center tap terminal, the second coil has a second center tap terminal, and the apparatus further comprises:
a first capacitor coupled between the in-phase terminal and a DC terminal;
a second capacitor coupled between the quadrature phase terminal and the DC terminal;
a third capacitor coupled between the reference terminal and the DC terminal;
a fourth capacitor coupled between the isolation terminal and the DC terminal;
a fifth capacitor coupled between the first center tap terminal and the DC terminal;
a sixth capacitor coupled between the second center tap terminal and the DC terminal;
a seventh capacitor coupled between the quadrature phase terminal and the isolation terminal;
an eighth capacitor coupled between the in-phase terminal and the reference terminal; and
a ninth capacitor coupled between the first and second center tap terminals.

26. A method comprising:
receiving a first signal;
responsive to a power level of the first signal being below a threshold:
providing a second signal having a first power level using a first amplifier to an in phase terminal of a quadrature hybrid combiner;
responsive to a power level of the first signal being above the threshold:
providing a third signal having a second power level using the first amplifier to the in phase terminal; and
providing a fourth signal having a third power level higher than the first and second power levels using a second amplifier to a quadrature phase terminal of the quadrature hybrid combiner; and
providing a fifth signal at a reference terminal of quadrature hybrid combiner based on the second signal or a combination of the third and fourth signals as an output signal.
